(19) United States
(12) Patent Application Publication
(10) Pub. No.: US 2014/0015545 A1
(43) Pub. Date: Jan. 16, 2014

(54) METHOD FOR INSPECTING HOLLOW FIBER FILTRATION MODULES

(71) Applicants: Peter E.M. Aerts, Hulst (NL); Steven D. Jons, Eden Prairie, MN (US)

(72) Inventors: Peter E.M. Aerts, Hulst (NL); Steven D. Jons, Eden Prairie, MN (US)

(73) Assignee: Dow Global Technologies LLC, Midland, MI (US)

(21) Appl. No.: 14/001,624

(22) PCT Filed: Mar. 21, 2012
(86) PCT No.: PCT/US2012/029851

§ 371 Date: Aug. 26, 2013

Related U.S. Application Data
(60) Provisional application No. 61/469,205, filed on Mar. 30, 2011.

(51) Int. Cl. G01R 27/32

(52) U.S. Cl. CPC G01R 27/32
USPC 324/629

(57) ABSTRACT

Analyze a hollow fiber filter module for defects by providing a membrane header assembly with a header having a conduit defined there-through by a wall with multiple holes and a hollow fiber membrane inserted into a hole, directing a probe device with a sensor through the conduit, receiving sensory response information with the sensor, the sensory response information containing information sufficient to identify defect in the form of a hole lacking a hollow fiber membrane, a hole that has a hollow fiber membrane inserted to a non-desired depth, or both and then interpreting the sensory response information to detect such defects if they exist.

### BACKGROUND OF THE INVENTION

1. Field of the Invention

The present invention relates to a method for inspecting hollow fiber filtration modules for proper fiber placement.

2. Description of Related Art

Hollow fiber filtration modules comprise a plurality of aligned semi-permeable hollow fiber membranes penetrating through the wall of a header. The header has material serving as a wall or walls that define a conduit through which liquid or gas can travel. A plurality of hollow fiber membranes extend through one or more than one wall of the header so as to extend from outside the conduit to inside the conduit. Typically, a resinous material (“potting material”) seals the hollow fiber membranes in place in the wall of the header. The hollow fiber membranes serve to filter fluid (either liquid or gas) that either travels from inside the conduit through the fiber membranes to the outside of the conduit or vice versa. Hollow fiber filtration modules are useful, for example, in membrane bio-reactor (MBR) applications.

In one type of hollow fiber filtration module the header has a multitude of holes extending through the walls so that the holes provide fluid communication between the inside and outside of the conduit. The holes are generally slightly larger in dimension than the cross section of hollow fiber membranes, which are inserted into the holes in the header during fabrication of the hollow fiber filtration module. After insertion of the hollow fiber membranes into the holes the potting material is added to seal the hollow fiber membranes in the holes. It is common for a hollow fiber filtration module to have thousands of such hollow fiber membranes inserted and sealed into holes through the header.

One concern in manufacturing hollow fiber filtration modules is misplacement of hollow fiber membranes with respect to holes through a header wall. Misplacement includes, for example, failing to insert a hollow fiber membrane into a hole (an empty hole) as well as inserting a hollow fiber membrane into a hole too deep or too shallow. An empty hole serves as a defect in the module through which unfiltered fluid can bypass filtration. Insertion of a hollow fiber too shallow in a hole can result in displacement of the fiber prior to potting and result in an empty hole. Inserting a fiber too deep can inhibit fluid flow from within the hollow fiber or through the conduit. Discovering defects such as these in a hollow fiber filtration module after fabrication may require discarding of the module. It is desirable to be able to discover such defects during fabrication of a module, particularly prior to application of the potting material, to allow for remedying the defect or recycling of the modules components rather than discarding of the defective module.

Various methods are available for detecting defects in modules. Classic approaches make use of the fact that flow of gas through an intact module is inhibited at differential pressures below the bubble point of fibers (see, for example, ASTM method D6908-03 entitled “Standard Practice for Integrity Testing of Water Filtration Membrane Systems”).

Visualization of bubbles from a surface may be used to identify defective fibers (see, for example U.S. Pat. No. 5,918,264, PCT publication W02006037234 and Japanese patent publications JP2007017171, JP2005013947 and JP62140607). Similarly, passage of large challenge particles through a module can also reveal defects and detection of particles near the surface can reveal leak locations (see, for example U.S. Pat. No. 5,411,682). Defective modules may also be identified by detecting noise emitted from air flow through a leak (see, for example U.S. Pat. No. 6,370,943 and US20040237654) or by observing temperature differential caused by gas flow (see, for example, JP2010082587 and U.S. Pat. No. 6,766,259). Visualization approaches are known that image an outer surface of a cut, potted scroll face to identify irregularities (see, for example, JP200411389A, JP2006091007A, JP2008246378A and JP7051549).

Despite these known detection methods, there remains a need for a quick method for analyzing hollow fiber filter modules for defects that can be used in real time during the manufacture of fiber filter modules, especially prior to application of potting material. Even more desirable is a method for detecting defects that is automated and integrated with the hollow fiber insertion procedure so that the insertion process ceases upon detection of a defect to allow for the defect to be remedied in real time during hollow fiber filter module manufacturing.

### BRIEF SUMMARY OF THE INVENTION

The present invention provides a solution to the problem of analyzing hollow fiber filter modules for defects during their manufacture. The analysis method of the present invention can be accomplished prior to application of potting material. The analysis method of the present invention can be automated and can be integrated with the hollow fiber insertion procedure so that the insertion process ceases upon detection of a defect to allow for the defect to be remedied in real time during hollow fiber filter manufacturing.

In a first aspect, the present invention is a method for analyzing a hollow fiber filter module for defects, the method comprising: (a) providing a membrane header assembly comprising a header having a conduit defined there-through by a wall with multiple holes defined all the way through the wall and a hollow fiber membrane inserted into a hole; (b) directing a probe device comprising a sensor through the conduit ; (c) receiving sensory response information with the sensor, the sensory response information containing information sufficient to identify defects in the form of a hole lacking a hollow fiber membrane, a hole that has a hollow fiber membrane inserted to an non-desired depth, or both; and (d) interpreting the sensory response information to detect such defects if they exist.

The present invention has utility as an analytical method for ensuring quality control during the manufacture of hollow fiber filter modules.

### BRIEF DESCRIPTION OF THE DRAWINGS

FIG. 1 illustrates a partially constructed single header filter module.

FIG. 2 illustrates a probe device comprising sensors that generate sensory response information through physical contact with hollow fiber membranes.

FIG. 3 illustrates a probe comprising sensors for detecting electromagnetic radiation within a conduit.

FIG. 4 illustrates a probe comprising an illumination means and a sensor within a conduit.

### DETAILED DESCRIPTION OF THE INVENTION

“Multiple” means two or more. “And/or” means “and, or as an alternative”. All ranges include endpoints unless otherwise indicated. “Length” refers to the largest dimension and “cross sections” are perpendicular to the length.

The method of the present invention is for analyzing a hollow fiber filter module (“filter module”) that comprises a membrane header assembly. Hollow fiber filter modules that can benefit from the method of this invention include both two header and single header designs. FIG. 1 illustrates an example of single header filter module 1. Filter module 1 comprises membrane header assembly (“header”) 200. Header 200 is hollow with walls 50 defining conduit 100, which extends through header 200. At least one wall 50 has holes 55 defined there-through that provide fluid communication from outside module 1 to inside conduit 100. Hollow fiber membranes 30 reside within holes 55. Filter module 1 in FIG. 1 only has a portion of holes 55 occupied by hollow fiber membranes 30, which would be the case parte-way through manufacturing of a filter module.

As evident in FIG. 1, the membrane header assembly (“header”) comprises a hollow header that defines a conduit through the header. The header has at least one wall that extends around the conduit. The conduit is desirably greater than 0.5 meters in length and can be 0.7 meters or more in length and is preferably at least 5 times greater, more preferably at least ten times greater than the smallest dimension of the conduit perpendicular to the length (that is, the smallest cross sectional dimension). At the same time, the conduit desirably has at least one dimension perpendicular to the length that is less than 10 centimeters, preferably six centimeters or less. Desirably the conduit has a cross sectional area that is less than 25 square centimeters. The header can be made of any material, but is generally made of plastic. The material should be inert to the fluid that it will be exposed to when it serves as a component of a hollow fiber filter module.

The wall of the header has multiple (typically, thousands) of holes defined in it that penetrate through the wall to provide fluid communication between the inside and outside of the conduit (that is, to connect the outside of the conduit with the inside of the conduit). Desirably, one wall contains a two-dimensional array of holes. Desirably, the distance between nearest holes is less than ten millimeters, preferably less than six millimeters. Definition of holes through the wall can occur during or after fabrication of the header.

Hollow fiber membranes pass through holes in the header wall and have an open end that resides within the header. An open end of the hollow fiber is membranes inserted into each of the holes during manufacturing of the filtration module. Depending on the insertion depth, the open end of the fiber may extend inside the conduit or it may remain within the wall of the header (that is, between the conduit and outside of the header). It is desirable for the fiber to remain in place once it has been inserted into a hole. The fiber can remain in place by frictional forces if the fiber has a major diameter that is greater than the hole diameter of the fiber. The fiber can rest on a surface or ledge within the conduit that keeps the fibers from penetrating through the holes further than is desired. Bending of the fibers to induce tension against a hole is also possible to help maintain fiber position within a hole.

A challenge in manufacturing quality hollow fiber filtration modules is to reproducibly insert thousands of hollow fibers membrane into the array of holes of a header while ensuring each hole contains a hollow fiber membrane and each hollow fiber membrane resides in the hole at the proper depth and doing so as quickly as possible. For example, it is typically desirable to insert between ten and 2000 hollow fiber membranes per minute into holes in a header. Large hole diameters are desirable to facilitate reliable placement of fibers during manufacturing. However, the larger the hole, the more likely the fiber will undesirably move within that hole during manufacturing. Smaller diameter holes are desirable for holding the fibers in place, but are more difficult to reliably position hollow fiber membranes into during the manufacturing process. Holes may be tapered so as to have a larger diameter proximate to the outside of the header and smaller diameter proximate to the inside of the conduit to aid in proper insertion of the fibers into each hole.

The type of hollow fiber membrane used in the present invention is not critical to the method of the present invention. The present invention is suitable for use with membrane header assemblies comprising any type of hollow fiber membranes. Typical hollow fiber membranes include those prepared from polysulfones, polyether sulfones, polyvinylidene fluorides (PVDF) and polyamides, commonly prepared by way of known phase inversion processes. Additional examples include membranes made from polyolefins such as polypropylene, polyethylene and related copolymers via known etching and stretching processes. The hollow fiber membranes typically have lengths within a range from 0.2 meters to two meters.

It is desirable for the membrane header assembly to have a hollow fiber membrane inserted all the way through each hole and into the conduit to a particular desirable depth. Desirably, at least one hole has a hollow fiber membrane inserted properly all the way through the hole when the method of the present invention is used. Once one or more hollow fiber membrane has been inserted into a hole the present invention is useful to detect if the hollow fiber membranes have indeed been inserted into the holes they are supposed to be in and if they have been inserted to the proper depth.

A proper membrane header assembly comprises a hollow fiber membrane within each hole and potting material applied to the hole to hold the hollow fiber membrane in place. The present invention serves as a method for detecting if a hollow fiber membrane has been properly inserted into each hole. Evaluation as to whether a hollow fiber membrane has been “properly inserted” into each hole means determining whether a hole contains a hollow fiber membrane and/or whether a hollow fiber membrane residing in a hole is at a proper depth within the hole. A defect occurs where a fiber is not properly inserted into a hole. One form of defect is an absence of a filter fiber from a hole that is supposed to contain a filter fiber. Another form of defect is a hollow fiber membrane that is in a hole, but not at a proper depth within that hole. The definition of “proper depth” will depend on the particular filter module but for a given filter module there will be a proper depth. Typically, the proper depth will encompass a range of depths that are acceptable. In some embodiments, a proper depth will include insertion to a depth that does not require the filter fiber to extend all the way through the wall and into the conduit of a header (that is, the filter fiber is inserted to a depth that is less than the thickness of the header wall). In other cases, the proper depth will require the filter fibers to penetrate into the conduit of a header. Detection of fibers that reside in a hole, but at an improper depth, are particularly valuable to be able to detect because they tend to appear properly inserted upon inspection from outside of the header. Hence, the method of the present invention, which analyzes for defects from inside the header conduit, is particularly valuable for detecting fibers at an improper depth. Also, detection of insertion depth from within the header conduit is advantaged because it avoids having to view particular holes through the obstruction of adjacent fibers.

The method of the present invention is useful for analyzing a filter module for defects during or after assembly of the filter module. The method of the present invention is particularly valuable when used during manufacturing of a filter module because it can be used to allow detection of defects prior to applying potting material. Defects identified after potting are more difficult to correct and, if corrected, typically result in filter modules undesirably having obvious evidence of repair. In a mass production environment, detection of a defect in a module after potting typically results in discarding the module. Detection of defects prior to applying potting material allows defects to be remedied prior to applying potting material or the defective membrane header assembly can be disassembled and the components recycled into a defect-free membrane header assembly.

The method of the present invention is desirably employed to analyze a filter module during manufacturing of the filter module. In particular, it is desirable to analyze for defective positioning of a fiber at the time the fiber is attempted to be inserted in a hole. At that time, there is more space around the hole and fiber being analyzed. Moreover, detection of a defect can allow for automated cessation of the manufacturing process and remedying of the defect. In one embodiment, each fiber is analyzed for proper insertion before the next fiber in the process is inserted. Alternatively, or additionally, a series (such as a row) of fibers is analyzed for proper insertion or defects before the next series of fibers is inserted. Analyzing individual fibers or one dimensional arrays of fibers (for example, a row) during manufacturing is desirable over analyzing a two dimensional array of fibers after they have been inserted because individual fibers and one dimensional arrays are easier to analyze and, in particular, allow for easier access to defects in order to remedy the defects than is available with two dimensional arrays of fibers.

The method of the present invention, whether used during or after assembly of a filter module, involves translating a probe device (or simply “probe”) through the conduit of the header. The probe device has dimensions small enough to fit within the conduit of a header. The probe device comprises a sensor. The sensor receives different stimuli depending on whether it is detecting a defect or not within a header. The stimuli can be, for example, presence or absence of physical contact with a hollow fiber membrane, different quantities of light transmitted through a hole or reflected off from a conduit wall or hollow fiber membrane. The stimuli are also referred to herein as “sensory response information”. The sensor receives sensory response information either continuously or intermittently at certain points as it translates within the conduit of a header. The sensory response information contains information sufficient to determine if there are defects in the form of improperly inserted hollow fiber membranes. The method further includes collecting and interpreting the sensory response information to identify if any such defects exist.

Desirably, translation of the probe device through the conduit is controlled so that the location of the holes being analyzed for defects is determinable. Generally, the location of holes being analyzed is determinable by tracking the location of the probe device and/or the sensor of the probe device as the probe device translates through the conduit of a header. For optimal control of the probe in regards to knowing its precise location it is desirable that motion of the probe in a dimension perpendicular to the length of the conduit (“perpendicular movement”) is minimal or even absent as the probe translates along the length of the conduit. Minimizing perpendicular movement of the probe can be accomplished many different ways. For example, the probe may comprise spring-biased wheels that hold it in a stable position relative to perpendicular movement. Alternatively, or additionally, a portion of the probe may engage guides in the header that prevent or minimize perpendicular movement of the probe as it translates through the conduit. For instance, the probe may comprise protrusions that fit within (mate with) indentations in the wall of the conduit (or vice versa, the walls can comprise protrusions and the probe indentations or a combination of both probe and walls having both mating indentations and protrusions). Desirably, the probe has cross sectional dimensions that are within three millimeters, preferably within two millimeters and more preferably within one millimeter of the corresponding cross sectional dimension of the conduit to minimize likelihood of perpendicular movement of the probe when inside the conduit.

One of ordinary skill in the art can identify any of a number of methods for tracking the location of a probe as it translates through a conduit of a header, all of which are within the broadest scope of the present invention. For example, mechanical positioning components (for example, threaded rods, gears, stepper motors and encoders) can be used in translating a probe through a conduit. It is also possible to use known reference points within a conduit to determine the probe's position. For example, a light sensor on a probe can detect light shining through empty holes in the conduit wall and count how many holes the probe and sensor pass to get to a specific location in order to identify the location of the sensor in the conduit.

The sensor on the probe can be an “active” sensor or a “passive” sensor. Both active and passive sensors “detect” stimuli by receiving the stimuli. An active sensor generates a signal based on the stimulus it receives. For example, an active sensor may generate an electric current upon receiving a certain magnitude of stimulus and no electric current upon receiving less than that certain magnitude of stimulus (or vice versa). Such an active sensor is a digital active sensor. The active sensor can also be analog and a signal in proportion to the magnitude of stimulus it receives. Active sensors include switches and photodiodes. A passive sensor merely collects stimuli it receives for directing to another device for processing (for example, either interpretation or to generate a digital or analog signal which is then interpreted). Passive sensors include ends of optical fibers that receive light, which is then directed through the optical fiber for remote processing.

The sensor on the probe can be one that determines the presence of a filter fiber at a certain position by physical contact, or lack thereof if the filter fiber is absent. Such a sensor is a “direct contact” sensor. Suitable direct contact sensors include spring-loaded switches (or buttons) that can be pushed against a fiber. Pressure sensitive sensors such as the devices disclose in U.S. Pat. No. 7,726,197 and U.S. Pat. No. 7,357,035 are also suitable. The present method can, for example, include positioning a direct pressure sensor below a hole at the desired depth of filter fiber insertion as insertion of a fiber is being attempted. If the filter fiber is inserted to the proper depth it will contact the sensor, otherwise it will not. Another option is to translate the sensor at the desired depth after insertion of a fiber has been attempted to determine if the sensor contacts the fiber in the intended location. The sensor can comprise an electrical signal generator that generates one type of electrical signal when a fiber contacts the sensor and a different type of signal when there is no contact with a fiber. The signal can be different levels of electrical current or electrical potential (including an absence of electrical current or potential). An artisan can readily identify many different ways to employ a pressure sensitive sensor to determine whether a filter fiber is present at a desired depth, all of which are embodied in the broadest scope of the present invention. The signal from the sensor is collected and analyzed to determine the presence or absence of a fiber at a proper height.

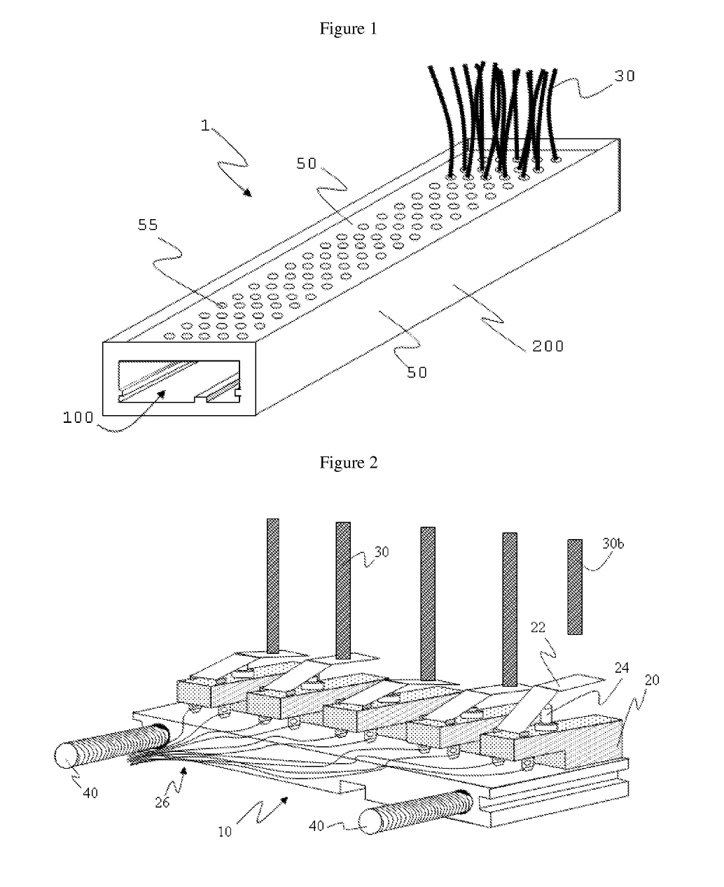

FIG. 2 illustrates an embodiment of a probe comprising a sensor that collects sensory response information through physical contact with hollow fiber membranes. Actually, the probe in FIG. 2 comprises multiple sensors to facilitate detection of a row of fibers while in a single position within a conduit. FIG. 2 illustrates probe 10 comprising sensors 20. Each sensor 20 comprises a lever arm 22 and a switch 24. Electrical current provide to each sensor 20 through wires 26 is allowed to flow through the sensor if a filter fiber 30 is inserted to a proper depth against lever arm 22, thereby depressing or merely contacting switch 24 and closing an electrical circuit within sensor 20. If a filter fiber 30 is not inserted far enough (for example, see filter fiber 30b) then electrical current is not detected through the corresponding sensor 20 and a defect is realized. Probe 10 in FIG. 2 is translated through a conduit along threaded rails 40 having a known thread count so as to provide accurate and precise positioning of probe 10 within a conduit by tracking the number of rotations threaded rod 40 undergoes in positioning probe 10. A probe such as probe 10 can be positioned under holes as filter fibers are being inserted to detect whether the fibers in that array are inserted into the holes and to the proper depth. Alternatively, a probe such as probe 10 can be translated under holes that are expected to contain filter fibers in which case if the filter fiber is present at the proper depth it will depress lever arm 22 and switch 24 to generate a signal indicating a fiber is present at the proper depth.

The sensor can also comprise or be a sensor that detects defects without requiring physical contact with a filter fiber membrane. Such sensors are “non-contact” sensors. Suitable non-contact sensors include those that receive or detect air pressure, sound waves and/or electromagnetic radiation. Non-contact sensors include those that receive or detect electromagnetic radiation transmitted through holes in a header and/or can work with reflective or break-beam principles and either create a signal based on a presence or absence of a certain amount of electromagnetic radiation or merely receive and transmits the electromagnetic radiation to another device that processes the transmission to determine if there is a defect or not. As with the direct contact sensors, a probe device can comprise a single sensor or an array of sensors. In fact, a probe device can comprise a combination of at least one direct contact sensor and at least one non-contact sensor.

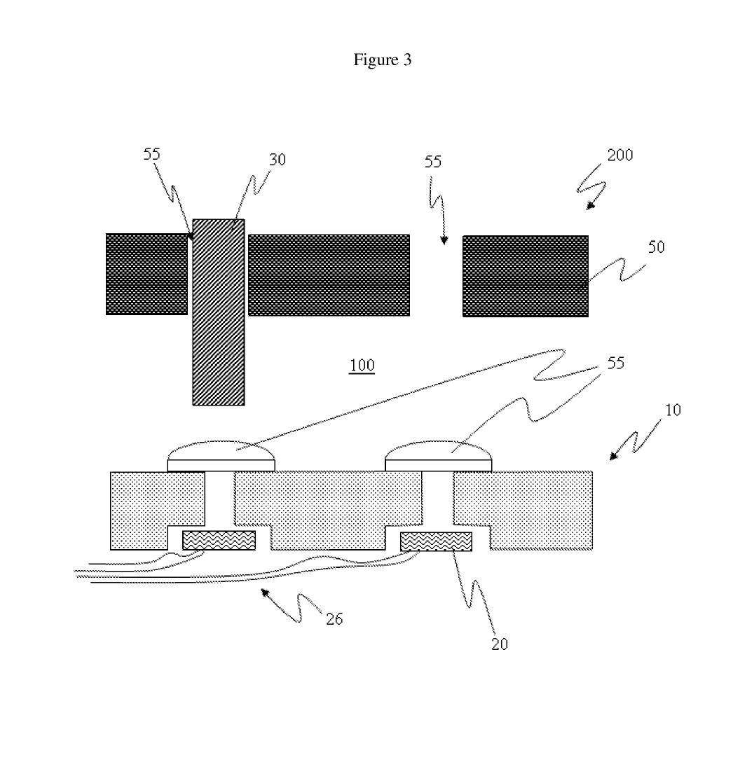

One way the method of the present invention can utilize a non-contact sensor to analyze for defects is to position a non-contact sensor that detects light (generally, but not necessarily visible light) within the conduit of a header directly below a hole in the header and then shine light onto the wall containing the hole from outside the header. If the sensor detects light at the position of the hole then that indicates a hollow fiber membrane is not in the hole. If the sensor fails to detect light then that indicates the hole does contain a hollow fiber membrane. FIG. 3 illustrates one example of such a probe and sensor combination. FIG. 3 illustrates probe 10 with a pair of photodiode sensors 20 inside of conduit 100 of header 200. Wall 50 defines holes 55. Hollow fiber membrane 30 extends through one of holes 55. Light shining from outside the header 200 can shine through the hole 55 that lacks a fiber membrane 30 and cause a response from the photodiode sensor 20 below that hole 55. Such a response would indicate lack of a fiber membrane 30 in that hole 55. Fiber 30 in the other hole 55 prevents light from penetrating through to sensor 20 below it and no signal is generated from that sensor, thereby revealing that a fiber membrane 30 is present in that hole 55. To increase sensitivity of light detection, probe 10 can further comprise lenses 15 (and/or apertures) that collect light that enters conduit 100 through a hole 55 and concentrate and/or direct it on a sensor 20 below the hole 55. Signals from sensors 20 can be sent from the sensor to a computer or other analyzer through wires 26.

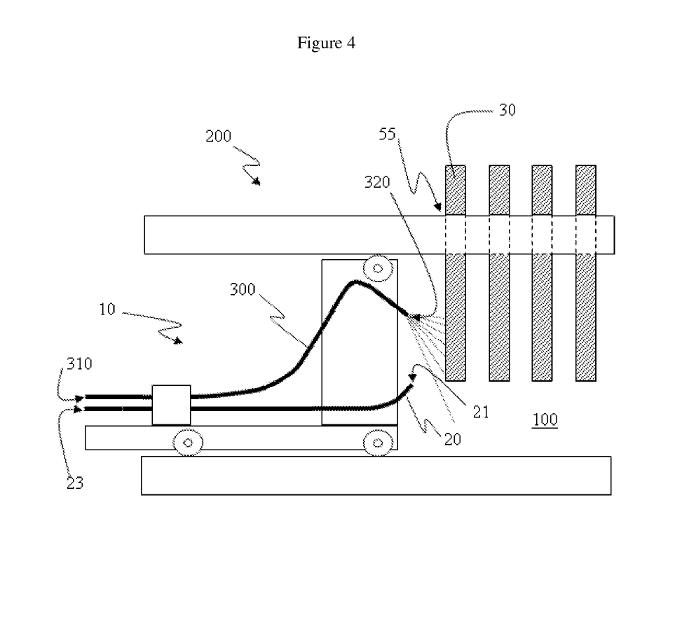

FIG. 4 illustrates another method of utilizing a non-contact sensor in the method of the present invention. A probe can comprise not only a sensor, but a source of signal to be detected. For instance, a probe can comprise both a source of light and a sensor of light. Probe 10 in FIG. 4 comprises both sensor 20 as well as a source of light in the form of illuminating means 300. Probe 10 is within conduit 100 and comprises both an illuminating means 300 and a sensor 20. Both illuminating means 300 and sensor 20 are fiber optics.

Light is applied to external end 310 of illuminating means 300 to shine light from inside end 320. Similarly, light that is incident on collecting end 21 of sensor 20 is transmitted through external end 23, which can then be further detected and/or analyzed using light sensors (for example, photodiodes, photomultiplier tubes, etc.). Probe 10 can be transported within conduit 100 of header 200 to proximate to a target hole 55 through wall 50 of interest. Light shining from inside end 320 of illuminating means 300 will reflect off from a hollow fiber membrane 30, if present through target hole 55, and increase the amount of light incident on collecting end 21 of sensor 20. If fiber membrane 30 is absent from target hole 55 then less light will be incident on collecting end 21 of sensor 20. The presence or absence of a fiber membrane 30 in a target hole 55 will be evident based on how much incident light is detected on collecting end 21 and transmitted through sensor 20. FIG. 4 illustrates a probe designed for analyzing a single hole for defects. However, probe 10 can comprise multiple sensor 20 elements and illuminating means 300 aligned in rows corresponding to rows of holes 55 in order to simultaneously analyze a row of holes for defects.

The probe device can comprise a sensor in the form of a camera that transmits visual images of the fibers and holes to allow a visual inspection from the inside of the conduit. Visual inspection of the transmitted images can reveal which holes lack a hollow fiber membrane by viewing images of the holes. Visual inspection of the transmitted images can also reveal the depth of the hollow fiber membranes by viewing images directed along the conduit and generally perpendicular to the hollow fiber membranes. For example a camera (such as a Cognex In-Sight™ 5400 brand micro camera; In-Sight is a trademark of Cognex Corporation) oriented at a 45 degree angle to both the hollow fiber membranes and the wall with holes defined there-through can be translated through a conduit to create an image for viewing ends of fiber membranes penetrating through a wall of the header and into the conduit. Analysis of the images can be done by visual inspection by a human operator or can be automated by computer using analysis software such as In-Sight Explorer, available from Cognex Corporation (Natick, Mass., USA).

A probe device can comprise multiple cameras with one viewing the holes and another viewing along the conduit so that determination of whether holes lack hollow fiber membranes and whether hollow fiber membranes are inserted to the proper depth can both be determined at the same time.

The probe device can comprise a sensor, such as a camera, that detects electromagnetic radiation other than that in the visible spectrum in addition to or alternatively to collecting images in the visual spectrum. For example, infrared or ultraviolet radiation can be used to collect images.

Likewise, a probe can comprise a sensor (or sensors) that can sense acoustical vibrations. Techniques similar to that described above for electromagnetic radiation can be used with acoustical waves instead of electromagnetic radiation. For example, acoustical waves can be directed at a wall of a header while a probe with an acoustical sensor is translated through the conduit of the header. Acoustical waves will penetrate through holes without fiber membranes to the sensors, which will detect more or stronger acoustical waves when passing holes lacking a fiber membrane. A probe within a conduit can also comprise an acoustical wave generator with an acoustical sensor and can operate similarly to the embodiment describe with FIG. 4. The time delay between the generation and sensing of acoustic signals can also be used to assess distances to fibers. It is possible to use acoustical sensors to record acoustical signals to detect the presence or absence of hollow fiber membranes in a holes as well as the depth of hollow fiber membranes within the holes. Detection of acoustical vibrations can be used similarly as electromagnetic radiation to detect presence or absence of hollow fiber membranes in holes as well as the depth of hollow fiber membranes within holes.

Collecting and interpreting sensory response information from a sensor is beneficially controlled by a computer. For example, both the movement of a probe and sensory response data collection from a sensor on the probe can be controlled by electronic signals from a computer. Alternatively, or additionally, a sensor can send sensory response information to a computer in the form of electronic signals. The computer can then interpret the sensory response information to identify defects.

Moreover, a computer is beneficial for controlling and tracking the position of the sensor as it travels through the conduit. By using a computer to track the position of the sensor as well as interpret the sensory response information from the sensor determination of the presence and location of defects can rapidly be detected as a sensor travels through a conduit of a header.

One benefit of computer controlling the probe's translation through the conduit and interpretation of sensory response information from a sensor on the probe is that the analysis method of the present invention can be incorporated in real time into the process of manufacturing a header for a hollow fiber filter module. That is, the method of the present invention can direct a probe with a sensor through the conduit of a header of the hollow fiber filter module as hollow filter fibers are being inserted into the holes in the header. The sensor can then detect whether hollow filter fibers are inserted properly into holes immediately after the hollow filter fiber is expected to be inserted. Moreover, it is desirable for the computer controlling the sensor and interpretation of the sensory response information from the sensor to be or be linked to a computer controlling the insertion of hollow filter fibers into the header so that if a defect is detected the computer can immediately stop the manufacturing process so the defect can be remedied.

The probe and sensor can be of any size or shape provided that it can fit within the conduit of a header. It is desirable if the probe design coordinates with the size and shape of the conduit so as to facilitate accurate and reproducible travel of the sensor through the conduit. For example the header can have slots defined within the walls of the conduit in which the probe engages to direct the travel of the probe through the conduit. Alternatively, or additionally, the shape of the probe can match the shape of the conduit so that the walls of the conduit conform to the shape of the probe.

What is claimed is:

1. A method for analyzing a hollow fiber filter module for defects, the method comprising:
(a) providing a membrane header assembly comprising a header having a conduit defined there-through by a wall with multiple holes defined all the way through the wall and a hollow fiber membrane inserted into a hole;
(b) directing a probe device comprising a sensor through the conduit;
(c) receiving sensory response information with the sensor, the sensory response information containing information sufficient to identify defects in the form of a hole lacking a hollow fiber membrane, a hole that has a hollow fiber membrane inserted to a non-desired depth, or both; and
(d) interpreting the sensory response information to detect such defects if they exist.

2. The method of claim 1, further characterized by analysis of a hole by steps (a)-(d) occurring before potting material is applied to the hole.

3. The method of claim 1, further characterized by tracking the position of the probe device as it travels through the conduit.

4. The method of claim 3, wherein a computer controls directing the probe device through the conduit, tracking of the position of the sensor device and interpreting the sensory response information.

5. The method of claim 1, further characterized by steps (a) through (d) occurring during a process of inserting hollow fiber membranes into the holes of the conduit walls.

6. The method of claim 5, further characterized by tracking the position of the probe device as it travels through the conduit and identifying the position of any of the defects; wherein steps (a)-(d) and the process of inserting hollow fiber membranes into the holes of the conduit walls are computer controlled and automated so that if a defect is detected the computer stops the process of inserting hollow fiber membranes.

7. The method of claim 1, wherein the sensor creates sensory response information upon detecting physical contact, acoustical waves or electromagnetic radiation.

8. The method of claim 7, wherein an emitter accompanies the sensor on the probe device and wherein the emitter emits acoustical waves and/or electromagnetic radiation that the sensor can detect.

9. The method of claim 1, wherein the sensor device contains an imaging sensor that transmits data sufficient to create a visual image of the conduit walls as the sensory device travels through the conduit.
